(19) United States
(12) Patent Application Publication
(10) Pub. No.: US 2025/0105023 A1
(43) Pub. Date: Mar. 27, 2025

(54) MANUFACTURING METHOD OF SEMICONDUCTOR DEVICE

(71) Applicant: Kioxia Corporation, Tokyo (JP)

(72) Inventors: Shunichi YONEDA, Yokkaichi Mie (JP); Kazuhiro MATSUO, Kuwana Mie (JP); Masaya TODA, Yokkaichi Mie (JP); Kota TAKAHASHI, Yokkaichi Mie (JP); Masaya NAKATA, Yokkaichi Mie (JP); Kenichiro TORATANI, Yokkaichi Mie (JP); Ha HOANG, Kuwana Mie (JP); Takuma DOI, Yokkaichi Mie (JP); Wakako MORIYAMA, Yokohama Kanagawa (JP)

(73) Assignee: Kioxia Corporation, Tokyo (JP)

(21) Appl. No.: 18/817,372

(22) Filed: Aug. 28, 2024

(30) Foreign Application Priority Data
Sep. 21, 2023 (JP) 2023-156500

(51) Int. Cl. H01L 21/46; C23C 8/12

(52) U.S. Cl. CPC H01L 21/46; C23C 8/12

(57) ABSTRACT

A manufacturing method includes loading a substrate into a chamber, the substrate including oxide semiconductor; configuring a temperature in the chamber to a first temperature; supplying an oxidizing gas into the chamber; lowering the temperature in the chamber from the first temperature; stopping supplying the oxidizing gas into the chamber after lowering the temperature; and unloading the substrate from the chamber after the temperature in the chamber reaches a second temperature lower than the first temperature.

### CROSS-REFERENCE TO RELATED APPLICATION

This application is based upon and claims the benefit of priority from Japanese Patent Application No. 2023-156500, filed Sep. 21, 2023, the entire contents of which are incorporated herein by reference.

### FIELD

Embodiments described herein relate generally to a manufacturing method of a semiconductor device.

### BACKGROUND

A semiconductor device including an oxide semiconductor is proposed. In the semiconductor device provided with the oxide semiconductor, it is desired to reduce oxygen deficiency in the oxide semiconductor and improve electrical characteristics.

### DESCRIPTION OF THE DRAWINGS

FIG. 1 is a circuit view showing an example of a circuit configuration of a semiconductor storage device according to the present embodiment.

FIG. 2 is a schematic sectional view showing an example of a physical configuration of the semiconductor storage device according to the present embodiment.

FIG. 3A is a schematic side view of a substrate processing apparatus.

FIG. 3B is a schematic plan sectional view of the substrate processing apparatus.

FIG. 4 is a flowchart of a manufacturing method of a semiconductor device according to the present embodiment.

FIG. 5 is a schematic view of a time change in a temperature in a chamber in a manufacturing method of a semiconductor device of a comparative example.

FIG. 6 is a schematic view of a time change in a temperature in a chamber in the manufacturing method of the semiconductor device according to the present embodiment.

FIG. 7 is a schematic view of the time change in the temperature in the chamber in the manufacturing method of the semiconductor device according to the present embodiment.

FIG. 8 is a schematic view of the time change in the temperature in the chamber in the manufacturing method of the semiconductor device according to the present embodiment.

### DETAILED DESCRIPTION

Embodiments provide a manufacturing method of a semiconductor device capable of improving electrical characteristics.

In general, according to one embodiment, a manufacturing method of a semiconductor device is disclosed. The manufacturing method includes loading a substrate into a chamber, the substrate including oxide semiconductor; configuring a temperature in the chamber to a first temperature; supplying an oxidizing gas into the chamber; lowering the temperature in the chamber from the first temperature; stopping supplying the oxidizing gas into the chamber after lowering the temperature; and unloading the substrate from the chamber after the temperature in the chamber reaches a second temperature lower than the first temperature.

Hereinafter, the present embodiment will be described with reference to the drawings. In order to facilitate understanding of the description, the identical elements will be denoted by the identical reference numerals as much as possible in each drawing, and the duplicate description will be omitted or simplified.

Each drawing may show an X-axis, a Y-axis, and a Z-axis. The X-axis, the Y-axis, and the Z-axis form a three-dimensional right-handed orthogonal coordinate. Hereinafter, the arrow direction of the X-axis may be referred to as the X-axis + direction, and the opposite direction to the arrow may be referred to as the X-axis − direction, and the same applies to other axes. The Z-axis + direction and the Z-axis − direction may also be referred to as an “upper side” and a “lower side”, respectively. In addition, a plane orthogonal to each of the X-axis, the Y-axis, or the Z-axis may be referred to as a YZ plane, a ZX plane, or an XY plane, respectively. In addition, the Z-axis direction may be referred to as an “up-down direction”. The terms “upper side”, “lower side”, and “up-down direction” are terms indicating a relative positional relationship in the drawing, and are not terms for determining an orientation based on a vertical direction.

Further, unless otherwise specified, the dimensions and the like of the elements shown in the drawings may be shown differently from the actual dimensions in order to facilitate understanding of the description.

In the present specification, the term “connection” includes not only a physical connection but also an electrical connection, and includes not only a direct connection but also an indirect connection via another object, unless otherwise specified.

In the present specification, the phrase “formed above” includes not only a case where the object is formed in contact with the upper side but also a case where the object is formed above through another object, unless otherwise specified. The same applies to a case of “formed below” or the like.

### First Embodiment

Hereinafter, a semiconductor storage device 101 (hereinafter, also referred to as the semiconductor device 101) which is a semiconductor device manufactured by the manufacturing method of a semiconductor device according to the embodiment of the present disclosure and which includes a memory cell array in which a plurality of memory cells are arranged will be described. The semiconductor device and the manufacturing method thereof according to the embodiment of the present disclosure will be described below with reference to a DRAM as an example, but the embodiment of the present disclosure is not limited thereto. The semiconductor device according to the embodiment of the present disclosure may be another semiconductor device including an oxide semiconductor, and the manufacturing method of a semiconductor device according to the embodiment of the present disclosure may be used as a manufacturing method of such the other semiconductor device.

### Circuit Configuration of Semiconductor Storage Device

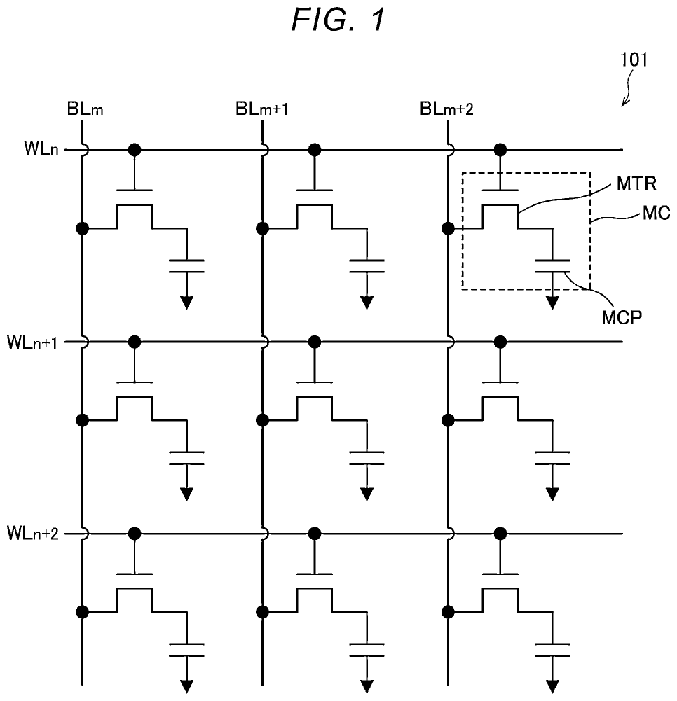

FIG. 1 shows an example of a circuit configuration of the semiconductor storage device 101 according to the present embodiment. As shown in the figure, the semiconductor storage device 101 includes the memory cell array configured with a plurality of memory cells MC, a plurality of word lines WL, and a plurality of bit lines BL. In the figure, as an example of the plurality of word lines WL, a word line WLₙ, a word line WLₙ₊₁, and a word line WLₙ₊₂ are shown (here, n is a positive integer). In addition, as an example of the plurality of bit lines BL, a bit line BLₘ, a bit line BLₘ₊₁, and a bit line BLₘ₊₂ are shown (here, m is a positive integer).

The plurality of memory cells MC are arranged in a matrix shape, for example, to form the memory cell array. The memory cell MC is provided with a memory transistor MTR, which is a field effect transistor (FET), and a memory capacitor MCP.

The plurality of memory cells MC provided along the row direction are connected to the word line WL (for example, the word line WLₙ) corresponding to a row (for example, an n-th row) to which the memory cells MC belong. Specifically, the gate of the memory transistor MTR provided in the memory cell MC is connected to the word line WL corresponding to the row to which the memory cell MC belongs.

The plurality of memory cells MC provided along the column direction are connected to the bit line BL (for example, the bit line BLₘ₊₂) corresponding to the column (for example, an m+2-th column) to which the memory cells MC belong. Specifically, one of the source and the drain of the memory transistor MTR is connected to the bit line BL corresponding to the column to which the memory cell MC belongs. Meanwhile, the other of the source and the drain of the memory transistor MTR is connected to one electrode of the memory capacitor MCP provided in the memory cell MC.

The memory capacitor MCP is configured to store data by holding charges. The memory capacitor MCP includes one capacitor electrode connected to the other of the source and the drain of the memory transistor MTR, a capacitor dielectric film, and the other capacitor electrode facing the one capacitor electrode via the capacitor dielectric film.

In the above configuration, a voltage is applied to a predetermined word line WL to switch the predetermined plurality of memory transistors MTR connected to the word line WL. Further, by flowing a current through the bit line BL connected to the predetermined memory transistor MTR, it is possible to store charges, via one memory transistor MTR, in the memory capacitor MCP connected to the memory transistor MTR. As described above, each of the memory cells MC of the memory cell array is configured to store data.

### Physical Configuration of Semiconductor Storage Device

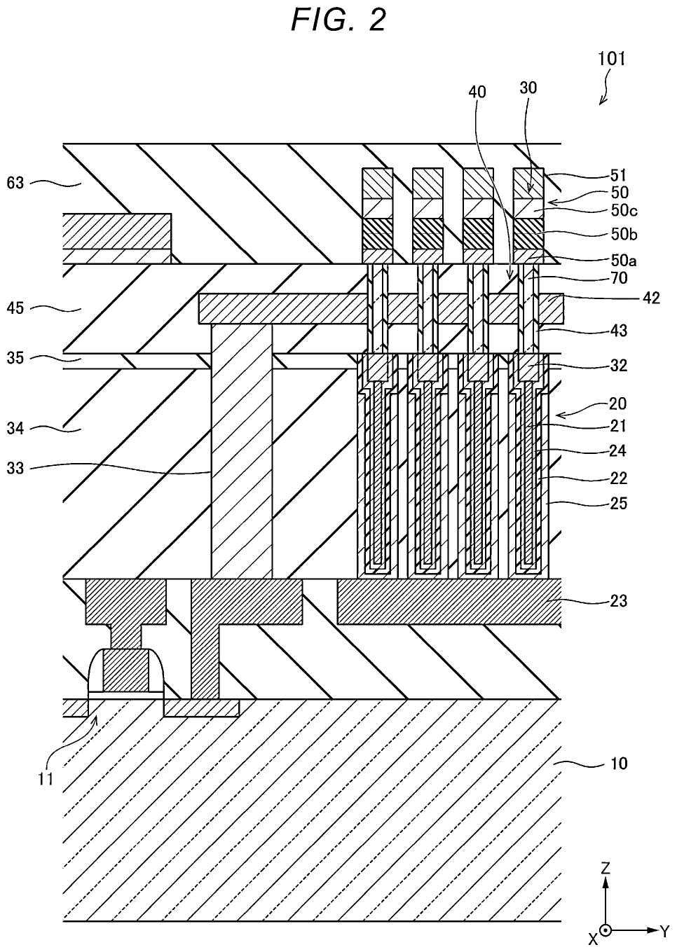

FIG. 2 is a schematic sectional view showing a physical configuration of the semiconductor storage device 101 according to the present embodiment. As shown in FIG. 2, the semiconductor storage device 101 is provided with a semiconductor substrate 10, a logic circuit 11, a capacitor 20, a field effect transistor 40, a conductor 33, insulating layers 34, 35, 45, and 63, a semiconductor device 30, and a conductive layer 51.

The capacitor 20 corresponds to the memory capacitor MCP in FIG. 1. The field effect transistor 40 corresponds to the memory transistor MTR in FIG. 1. The semiconductor device 30 corresponds to the memory cell MC in FIG. 1. The semiconductor device 30 includes the capacitor 20 and the field effect transistor 40.

The capacitor 20 is a pillar-type capacitor extending in the up-down direction. The capacitor 20 includes a conductor 21, a capacitor electrode 24 electrically connected to the conductor 21, a capacitor electrode 25 facing the capacitor electrode 24, an insulating film 22 provided between the capacitor electrode 24 and the capacitor electrode 25, and a conductor 23 electrically connected to the capacitor electrode 25 and for applying a constant voltage (for example, a ground voltage) to the capacitor electrode 25.

The conductor 21 has an upper end portion in contact with a lower end of a lower electrode 32 and extends downward from the upper end portion. The capacitor electrode 24 is electrically connected to the lower electrode 32 and the conductor 21, and covers the side surface of the lower electrode 32 and the side surface of the conductor 21 in the present embodiment. The insulating film 22 covers the side surface of the capacitor electrode 24. The capacitor electrode 25 has a lower end that surrounds the side surface and the bottom surface of the insulating film 22 on the lower side and that is in contact with an end surface of the conductor 23 on the upper side.

The conductor 21 may be made of a material such as amorphous silicon. The insulating film 22 may be made of a material such as hafnium oxide. The conductor 23 and the capacitor electrodes 24 and 25 may be made of materials such as tungsten (W) and titanium nitride (TiN).

The field effect transistor 40 includes the lower electrode 32, an oxide semiconductor 70, a gate insulating film 43, a conductive layer 42, and an upper electrode 50. The oxide semiconductor 70 is formed above the lower electrode 32 and is electrically connected to the lower electrode 32. The oxide semiconductor 70 corresponds to a channel of the field effect transistor 40. The gate insulating film 43 surrounds the side surface of the oxide semiconductor 70. The conductive layer 42 faces the oxide semiconductor 70 via the gate insulating film 43, and corresponds to the gate electrode of the field effect transistor 40.

In the present embodiment, the field effect transistor 40 is formed above the capacitor 20. In addition, the field effect transistor 40 is a vertical transistor including a channel extending in the up-down direction, as will be described later. The position of the capacitor 20 in the Z direction as shown in FIG. 2 is different from the position of the field effect transistor 40 in the Z direction.

For example, in the embodiment shown in FIG. 2, a virtual straight line including a central axis extending in the up-down direction of the capacitor 20 penetrates a channel extending in an up-down direction of the field effect transistor 40. Therefore, it is possible to increase the density of the memory cell array.

As described below, the semiconductor storage device 101 of the present embodiment is further provided with at least a part of the logic circuit 11 below the capacitor 20, so that further integration of the semiconductor storage device is possible. Meanwhile, the semiconductor storage device 101 may include another capacitor capable of storing charges instead of the three-dimensional capacitor shown in the present embodiment.

The lower electrode 32 is in contact with the lower end of the oxide semiconductor 70 at the upper end and is in contact with the conductor 21 of the capacitor 20 at the lower end, so that the lower electrode 32 supplies the capacitor 20 with charges. The lower electrode 32 is, for example, an oxide conductor containing indium (In), tin (Sn), and oxygen (O). The lower electrode 32 contains, for example, indium tin oxide.

The oxide semiconductor 70 includes an upper end portion corresponding to one of the drain and the source of the field effect transistor 40, a lower end portion corresponding to the other of the drain and the source, and a central portion provided between the upper end portion and the lower end portion and corresponding to the channel. The oxide semiconductor 70 is formed in a columnar shape extending in the up-down direction. Therefore, the field effect transistor 40 is a so-called vertical transistor.

The oxide semiconductor 70 is a semiconductor in which oxygen deficiency acts as a donor. The oxide semiconductor 70 contains, for example, at least one element selected from the group configured with indium (In), gallium (Ga), silicon (Si), aluminum (Al), titanium (Ti), and tin (Sn), and zinc (Zn) and oxygen (O). Specifically, the oxide semiconductor 70 is a layer containing an oxide of indium, gallium, and zinc, that is, indium gallium zinc oxide. The oxide semiconductor 70 has, for example, an amorphous structure. Meanwhile, the oxide semiconductor 70 may be another type of oxide semiconductor.

The gate insulating film 43 contains a silicon nitride film containing silicon and nitrogen, for example.

The conductive layers 42 correspond to gate electrodes of the field effect transistor 40, and face each other via the central portion between the upper end and the lower end of the oxide semiconductor 70 and the gate insulating film 43. The conductive layer 42 is made of, for example, tungsten (W).

The upper electrode 50 is electrically connected to the oxide semiconductor 70 and is formed above the oxide semiconductor 70.

The upper electrode 50 includes a metal oxide layer 50a, a barrier metal layer 50b, and a metal film 50c.

The upper electrode 50 is in contact with the upper end of the oxide semiconductor 70 and is provided above the oxide semiconductor 70. The metal oxide layer 50a is, for example, an oxide conductor containing indium (In), tin (Sn), and oxygen (O). The upper electrode 50 contains, for example, indium tin oxide.

In the present embodiment, the barrier metal layer 50b is electrically connected to the metal oxide layer 50a and is formed in contact with the metal oxide layer 50a above the metal oxide layer 50a.

In the present embodiment, the barrier metal layer 50b is a barrier metal, and is made of, for example, titanium nitride (TiN).

The metal film 50c is electrically connected to the barrier metal layer 50b and is formed above the barrier metal layer 50b. The metal film 50c is made of tungsten (W).

The upper electrode 50 is electrically connected to the conductive layer 51 (example of a “signal line”) corresponding to the bit line BL. The conductive layer 51 is provided, for example, in contact with the metal film 50c, which is the upper end of the upper electrode 50.

The logic circuit 11 includes a peripheral circuit such as a decoder for selecting one or the plurality of memory cells MC from the plurality of memory cells MC of the semiconductor storage device 101, a sense amplifier connected to the bit line BL, and a register configured with an SPAM.

The logic circuit 11 may be provided with a CMOS circuit having a field effect transistor of a P-channel type field effect transistor (Pch-FET) and an N-channel type field effect transistor (Nch-FET), which are formed by a CMOS process.

The field effect transistor of the logic circuit 11 may be formed using, for example, the semiconductor substrate 10 such as a single crystal silicon substrate. The Pch-FET and the Nch-FET are so-called horizontal (planar) field effect transistors having a channel region, a source region, and a drain region in the semiconductor substrate 10, and having a channel for causing a carrier to flow in the X-axis direction or the Y-axis direction substantially parallel to the surface of the semiconductor substrate 10 in a region close to the surface of the semiconductor substrate 10. FIG. 2 shows an example of a horizontal field effect transistor provided in such the logic circuit 11.

The conductor 33 is provided with wiring that electrically connects the logic circuit 11 and the semiconductor device 30. The conductor 33 may be provided with via wiring extending in the up-down direction and wiring extending in the horizontal direction, and for example, as shown in FIG. 2, may have via wiring that extends in the Z-axis direction and connects the word line WL and the logic circuit 11 provided on the semiconductor substrate 10. The conductor 33 may be made of, for example, copper.

The insulating layer 34 is formed between the capacitors 20 to insulate the plurality of capacitors 20 from each other. The insulating layer 35 is provided above the insulating layer 34. The insulating layer 45 is formed between the oxide semiconductors 70 to insulate the plurality of oxide semiconductors 70 from each other. The insulating layer 63 is formed between the upper electrodes 50, between the conductive layers 51, and above the conductive layer 51 to insulate the plurality of upper electrodes 50 from each other and the plurality of conductive layers 51 from each other.

The insulating layers 34 and 45 are configured with, for example, a silicon oxide film containing silicon and oxygen. The insulating layer 35 is configured with, for example, a silicon nitride film containing silicon and nitrogen so that the insulating layer 35 also functions as a protective layer. The insulating layer 63 is configured with, for example, a silicon oxide film containing silicon and oxygen, or a silane film containing silicon and hydrogen.

With the semiconductor storage device 101 having the above configuration, at the time of writing information, a voltage is applied to the word line WL selected by the logic circuit 11 to make the field effect transistor 40 connected to the word line WL conductive, and a voltage is applied to the bit line BL selected by the logic circuit 11, so that information can be recorded by storing charges in the memory capacitor MCP from the bit line BL via the channel of the field effect transistor 40. In addition, at the time of reading information, when the voltage is applied to the word line WL selected by the logic circuit 11 to cause the field effect transistor 40 connected to the word line WL to be conductive, the voltage that fluctuates depending on whether the memory capacitor MCP stores charges in the bit line BL selected by the logic circuit 11 is sensed, and thus it is possible to read information.

### Configuration of Substrate Processing Apparatus

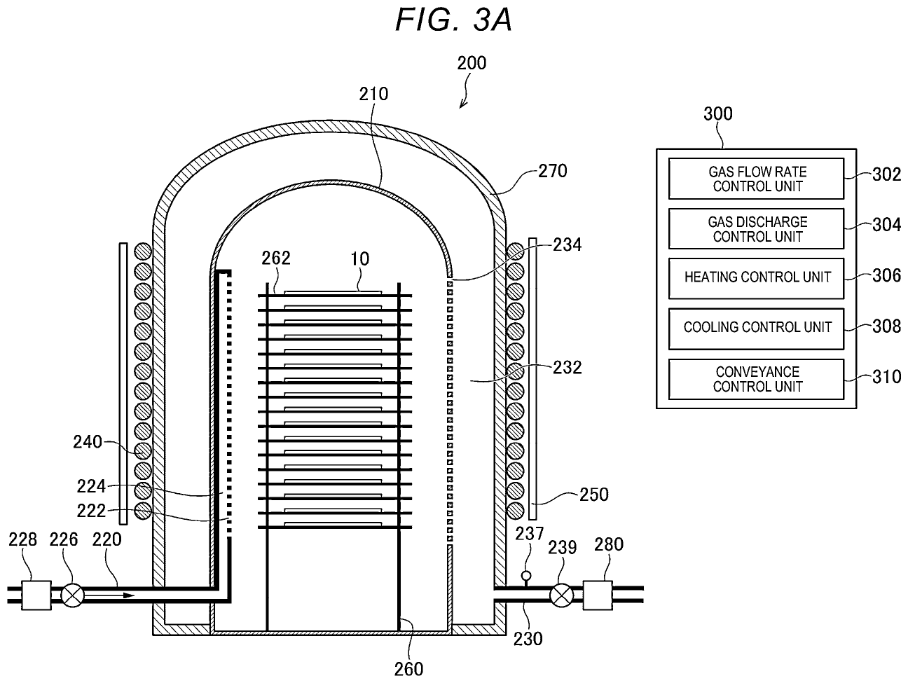

With reference to FIGS. 3A and 3B, a configuration of a substrate processing apparatus 200 used in implementing the manufacturing method of a semiconductor device according to the present embodiment will be described. FIG. 3A is a schematic side view of the substrate processing apparatus 200. FIG. 3B is a schematic plan sectional view of the substrate processing apparatus 200. The substrate processing apparatus 200 can be used as a processing furnace (chamber) used in the manufacturing method of a semiconductor device of the present embodiment.

As shown in FIGS. 3A and 3B, the substrate processing apparatus 200 includes a processing furnace 210 (chamber), a gas supply unit 220, a gas discharge unit 230, a heating unit 240, a cooling unit 250, a wafer support unit 260, a vacuum pump 280, and a control unit 300.

The processing furnace 210 is a cylindrical shape having a hemispherical upper end and is formed in an outer tube 270. The processing furnace 210 and the outer tube 270 include quartz.

The control unit 300 includes a gas flow rate control unit 302, a gas discharge control unit 304, a heating control unit 306, a cooling control unit 308, and a conveyance control unit 310.

The gas supply unit 220 includes a gas supply chamber 222 provided in the processing furnace 210, a plurality of gas supply ports 224 provided on a side wall of the gas supply chamber 222, a gas supply valve 226, and a mass flow controller (MFC) 228. The gas supply unit 220 supplies a gas into the processing furnace 210. The supply of the gas into the processing furnace 210 is controlled by the control unit 300. The gas flow rate control unit 302 of the control unit 300 is electrically connected to the gas supply valve 226 and the MFC 228. The gas flow rate control unit 302 controls the flow rate of the processing gas supplied into the processing furnace 210 and the time at which the processing gas is supplied into the processing furnace 210 by controlling the gas supply valve 226 and the MFC 228.

The plurality of gas supply ports 224 supply the gas to a wafer 10 supported by the wafer support unit 260 in a uniform manner. The gas supply unit 220 further has one or a plurality of gas supply sources (not shown) and supplies one or a plurality of types of gas.

The gas discharge unit 230 has a gas discharge chamber 232 provided between the processing furnace 210 and the outer tube 270, a plurality of gas discharge ports 234 provided on a side wall of the gas discharge chamber 232, a pressure sensor 237, and a gas discharge valve 239. The vacuum pump 280 is provided downstream of the gas discharge valve 239. The gas discharge unit 230 discharges the gas from the processing furnace 210. The discharge of the gas from the processing furnace 210 is controlled by the control unit 300. The pressure sensor 237 measures a pressure in the processing furnace 210. The pressure sensor 237, the gas discharge valve 239, and the vacuum pump 280 are electrically connected to the gas discharge control unit 304 of the control unit 300. For example, the gas discharge control unit 304 controls the gas discharge valve 239 and the vacuum pump 280 based on a pressure value in the processing furnace 210 measured by the pressure sensor 237, and thus controls the discharge amount and the time of the discharge of the processing gas from the processing furnace 210. Further, the gas discharge control unit 304 controls the pressure in the processing furnace 210. For example, the gas discharge control unit 304 controls the time at which the inside of the processing furnace 210 is vacuum-drawn and the pressure inside the processing furnace 210 when the inside of the processing furnace 210 is vacuum-drawn.

The plurality of gas discharge ports 234 remove (for example, discharge) the gas from the wafer 10 supported by a plurality of wafer supports 262 in a uniform manner. The gas discharge port 234 is provided in, for example, the processing furnace 210. For example, the gas discharge chamber 232 is provided between the gas discharge port 234 and the outer tube 270.

The heating unit 240 is disposed outside the outer tube 270, has an RF coil, and heats the processing furnace 210 via, for example, induction heating. The heating of the processing furnace 210 via the heating unit 240 is controlled by the heating control unit 306 of the control unit 300.

The cooling unit 250 is disposed outside the heating unit 240, and a cooling medium flow path through which, for example, cooling water as a cooling medium can flow is formed therein. The cooling unit 250 has a cooling medium removal unit (not shown), and removes the cooling medium used for cooling when the cooling of the processing furnace 210 is completed or the like. The cooling of the processing furnace 210 via the cooling unit 250 is controlled by the cooling control unit 308 of the control unit 300.

The wafer support unit 260 is provided in the processing furnace 210. The wafer support unit 260 supports the wafer (substrate 10) to be processed in the processing furnace 210. Loading and unloading of the wafer to and from the processing furnace 210 are controlled by the conveyance control unit 310 of the control unit 300, for example, by driving a wafer conveyance device (not shown).

The substrate processing apparatus 200 may further include one or a plurality of temperature measurement units that measure a temperature in the processing furnace 210. The heating control unit 306 and the cooling control unit 308 of the control unit 300 control the heating unit 240 and the cooling unit 250 based on the temperature in the processing furnace 210 measured by the temperature measurement unit.

### Manufacturing Method of Semiconductor Device

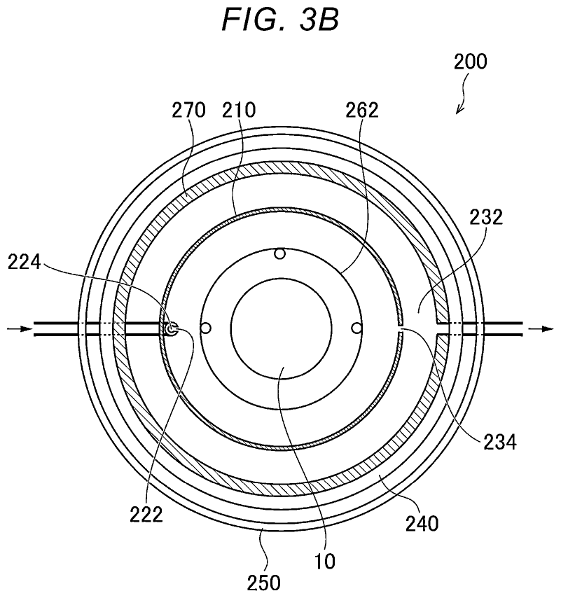

The manufacturing method of a semiconductor device according to the embodiment of the present disclosure will be described with reference to FIG. 4.

The manufacturing method of a semiconductor device according to the present embodiment is the manufacturing method of the semiconductor device 101 having the oxide semiconductor 70, the manufacturing method includes loading a substrate on which the oxide semiconductor is formed into a chamber (processing furnace 210 (FIGS. 3A and 3B or the like), setting a temperature in the chamber to a first temperature, supplying an oxidizing gas into the chamber, lowering the temperature in the chamber from the first temperature, stopping the supply of the oxidizing gas into the chamber after starting the temperature lowering, and unloading the substrate from the chamber after the temperature in the chamber reaches a second temperature lower than the first temperature. The manufacturing method of a semiconductor device according to the embodiment of the present disclosure may be used, for example, for manufacturing the semiconductor device having the oxide semiconductor described above.

Hereinafter, the manufacturing method of a semiconductor device according to the embodiment of the present disclosure will be described with reference to FIG. 4. The manufacturing method of a semiconductor device according to the present embodiment shown in FIG. 4 may be implemented, for example, in a step of supplying oxygen to a layer or a film formed of a metal oxide that exhibits semiconductor characteristics, such as the oxide semiconductor 70 in a manufacturing method of a semiconductor device.

As shown in FIG. 4, first, the substrate 10 on which the oxide semiconductor is formed is loaded into the chamber (S402). The substrate 10 has, for example, the structure shown in FIG. 2. The substrate 10 may include the oxide semiconductor 70, and for example, the upper electrode 50, the conductive layer 51, and the insulating layer 63 need not be provided.

Next, the temperature in the chamber is set to the first temperature (S404).

Next, an oxidizing gas is supplied into the chamber (S406).

Next, the temperature in the chamber is lowered from the first temperature (S408).

After the temperature lowering is started, the supply of the oxidizing gas is stopped (S410).

Subsequently, after the temperature in the chamber reaches the second temperature lower than the first temperature, the substrate 10 is unloaded from the chamber (S412). At this time, the temperature in the chamber is lowered to the second temperature.

In the manufacturing method of a semiconductor device according to the present embodiment, for example, the oxide semiconductor 70 formed in the substrate 10 can be supplied with oxygen by supplying the oxidizing gas into the chamber into which the substrate 10 on which the oxide semiconductor 70 is formed is loaded (for example, the chamber into which the substrate 10 is loaded). For example, oxygen that passes through the insulating layer 63 (see FIG. 2) is supplied to the oxide semiconductor 70. In the manufacturing method of a semiconductor device according to the present embodiment, as described below, the desorption of oxygen supplied to the oxide semiconductor 70 can be reduced, and as a result, the oxide semiconductor 70 can have a sufficient amount of oxygen.

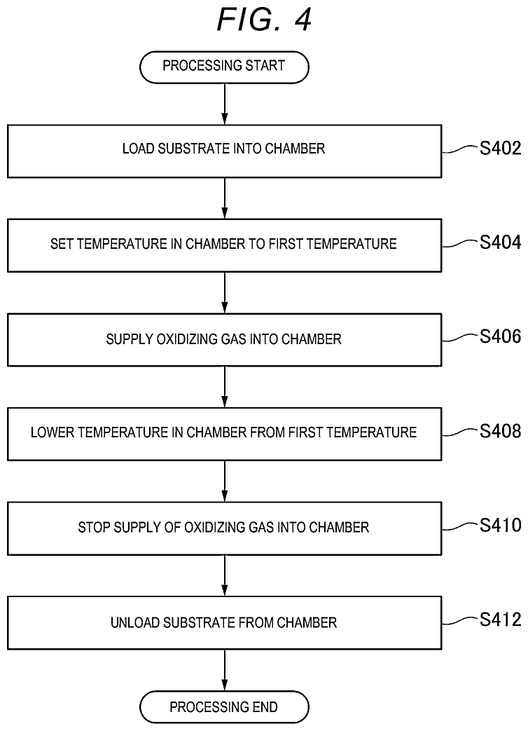

A manufacturing method of a semiconductor device of a comparative example will be described with reference to FIG. 5. FIG. 5 schematically shows a time (horizontal axis) change in a temperature (vertical axis) in a chamber in the manufacturing method of a semiconductor device of the comparative example.

In FIG. 5, the upper stage shows the gas supplied into the chamber.

In the manufacturing method of a semiconductor device of the comparative example, a substrate is loaded into the chamber at the time t50. The temperature in the chamber when the substrate is loaded is, for example, 400° C. When the substrate is loaded, a nitrogen gas is supplied into the chamber. The nitrogen gas may be supplied into the chamber before the substrate is loaded.

Thereafter, from the time t51, the nitrogen gas in the chamber is removed by using a vacuum pump, and the inside of the chamber is made a vacuum. In some cases, in the chamber used for the processing, the supply of the gas into the chamber and evacuation can be simultaneously performed. In such a case, the nitrogen gas may be removed from the chamber by stopping the supply of the nitrogen gas into the chamber at the time t51.

Subsequently, an oxidizing gas is supplied into the chamber from the time t52. As will be described later, for example, an ozone gas is supplied as the oxidizing gas, and thereby, for example, oxygen is supplied to the substrate in the chamber (specifically, for example, the oxide semiconductor provided on the substrate) at at least a part of the period from the time t52 to the time t53.

Next, from the time t53 to the time t54, the oxidizing gas is removed by using the vacuum pump to make the inside of the chamber vacuum again, and then the nitrogen gas is supplied into the chamber at the time t54. The substrate is unloaded from the chamber in the nitrogen gas atmosphere at the time t55, and the processing ends.

In the manufacturing method of a semiconductor device of the comparative example, as shown in FIG. 5, the temperature in the chamber is maintained at substantially the same temperature (for example, about 400° C.) from loading the substrate into the chamber to unloading the substrate from the chamber. That is, while the oxidizing gas is supplied, the temperature in the chamber is maintained substantially constant. The temperature of the chamber when the supply of the oxidizing gas is started and the temperature of the chamber when the supply of the oxidizing gas is stopped are substantially the same.

It was found that when a process of supplying oxygen to a substrate having an oxide semiconductor is executed with the manufacturing method of a semiconductor device of the comparative example, the manufactured semiconductor device may not have desired electrical characteristics. For example, it was found that the current at a predetermined voltage in a transistor using an oxide semiconductor in a channel region exceeds a desired value.

It is considered that oxygen deficiency is present in the oxide semiconductor, which generates electrons which are carriers. Therefore, the transistor in which the channel region is formed using an oxide semiconductor may have the threshold voltage fluctuating in the negative direction. This is considered to be because the oxygen in the oxide semiconductor is desorbed because the chamber is at a high temperature even after the supply of the oxidizing gas is stopped. That is, it is considered that the oxygen supplied to the oxide semiconductor from the time t52 to the time t53 is desorbed from the oxide semiconductor from the time t53 to the time t55.

As a result of earnest study, the present disclosers and the like found that the electrical characteristics can be improved by stopping the supply of the oxidizing gas after the temperature lowering in the chamber is started.

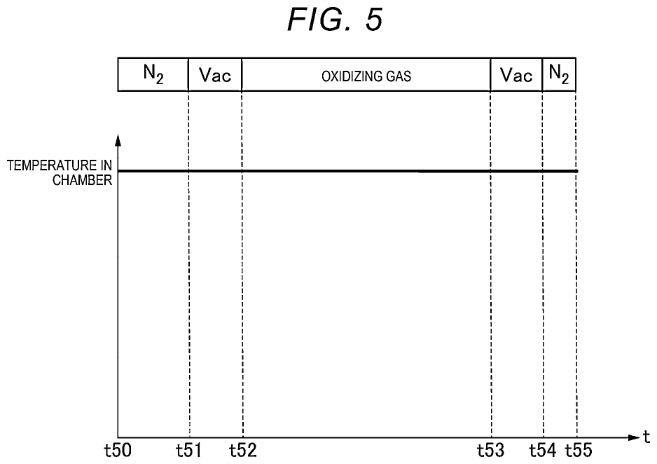

FIG. 6 shows the time change of the temperature in the chamber, which is the same as that in FIG. 5, in the manufacturing method of a semiconductor device of the present embodiment. As in FIG. 5, FIG. 6 also shows the gas supplied to the chamber.

As shown in FIG. 6, in the manufacturing method of a semiconductor device of the present embodiment, the substrate 10 is loaded into the chamber at the time t60. The temperature in the chamber when the substrate is loaded is, for example, 400° C. When the substrate is loaded, a nitrogen gas is supplied into the chamber. The nitrogen gas may be supplied into the chamber before the substrate 10 is loaded.

Thereafter, from the time t61, the nitrogen gas in the chamber is removed by using the vacuum pump 280, and the inside of the chamber is made a vacuum. As in the description with reference to FIG. 5, in the manufacturing method of a semiconductor device of the present embodiment, for example, in a configuration in which the nitrogen gas is supplied into the chamber and the chamber is evacuated at the same time from the time t60 to the time t61, the nitrogen gas may be removed from the chamber by stopping the supply of the nitrogen gas into the chamber at the time t61.

Subsequently, at the time t62, an oxidizing gas such as an ozone gas is supplied into the chamber. For example, oxygen is supplied to the substrate 10 in the chamber (specifically, for example, the oxide semiconductor 70 provided on the substrate 10) at at least a part of the period from the time t62 to the time t65.

Next, from the time t65 to the time t66, the oxidizing gas is removed by using the vacuum pump to make the inside of the chamber vacuum again, and then the nitrogen gas is supplied into the chamber at the time t66. The substrate 10 is unloaded from the chamber in the nitrogen gas atmosphere at the time t67, and the processing ends.

In the manufacturing method of a semiconductor device of the present embodiment, as shown in FIG. 6, the temperature in the chamber is lowered before the time t65 when the supply of the oxidizing gas is stopped (time t63). For example, at the time t62, the temperature in the chamber (first temperature in the present embodiment) is 400° C., and after the oxidizing gas is supplied in a state where the temperature in the chamber is maintained at 400° C., the temperature in the chamber is lowered from 400° C. to 200° C. (second temperature in the present embodiment) from the time t63 to the time t64 before the time t65. Thereafter, from the time t64 to the time t65, the second temperature is maintained, and then the inside of the chamber is vacuum-drawn from the time t65 in a state where the temperature in the chamber is maintained at the second temperature. Subsequently, at the time t66, the nitrogen gas is supplied into the chamber, and then, at the time t67, the substrate is unloaded. At the time t67, the temperature in the chamber is the second temperature, and the substrate is unloaded in a state where the temperature in the chamber is the second temperature.

While the oxidizing gas is supplied, the temperature in the chamber is not constant, and the temperature lowering is started at the time t63. After the temperature lowering, the supply of the oxidizing gas is stopped, and then the substrate 10 is unloaded.

In this way, the temperature in the chamber is lowered during the oxidizing gas supply period. Specifically, the temperature in the chamber is lowered from the first temperature to the second temperature while the oxidizing gas is supplied. After the temperature reaches the second temperature, the supply of the oxidizing gas is stopped. Therefore, the temperature in the chamber is lower at the time of the end of the supply of the oxidizing gas than at the time of the start of the supply of the oxidizing gas. In the example shown in FIG. 6, the temperature in the chamber at the time t62 is the first temperature, and the temperature in the chamber at the time t65 is the second temperature. Therefore, the temperature in the chamber at the time t65, which is the time of the end of the supply of the oxidizing gas, is lower than the temperature in the chamber at the time t62, which is the time of the start of the supply of the oxidizing gas.

According to the study by the present disclosers and the like, it was verified that the electrical characteristics of the semiconductor device including the substrate provided with the oxide semiconductor manufactured in this way can be improved. For example, it was found that the current at a predetermined voltage in a transistor using an oxide semiconductor to which oxygen is not supplied as in the present embodiment in a channel region is equal to or less than a desired value.

It is considered that in the manufacturing method of a semiconductor device of the present embodiment, an increase in oxygen deficiency may be able to be reduced because the oxygen supplied to the oxide semiconductor 70 in the chamber in an oxidizing gas atmosphere is less likely to be desorbed by lowering the temperature in the chamber before unloading the substrate 10.

It is considered that when the supply of the oxidizing gas is stopped in a state where the inside of the chamber is maintained at a relatively high temperature without lowering the temperature in the chamber as in the manufacturing method of the semiconductor device of the comparative example, the oxygen supplied to the oxide semiconductor is desorbed before the substrate is unloaded. This is because the inside of the chamber is at a high temperature when the supply of the oxidizing gas is stopped and the amount of the oxidizing gas in the chamber is reduced. In the present embodiment, when the supply of the oxidizing gas is stopped and the amount of the oxidizing gas in the chamber is reduced, the temperature is reduced to a level at which oxygen desorption from the oxide semiconductor does not occur. It takes time to lower the temperature in the chamber, so in the present embodiment, the temperature lowering is started from the middle of the supply of the oxidizing gas. Therefore, when the supply of the oxidizing gas is stopped, the temperature in the chamber is sufficiently low. That is, when the supply of the oxidizing gas is stopped, and when the inside of the chamber is in a vacuum, when the nitrogen gas is supplied, or when the substrate is unloaded, the temperature in the chamber is the second temperature.

The manufacturing method of a semiconductor device of the present embodiment and the manufacturing method of a semiconductor device of the comparative example were compared in terms of an oxygen amount contained in the oxide semiconductor. In the present embodiment, the oxygen amount is about more than twice that in the comparative example. In the present specification, the contained oxygen amount can be measured by, for example, a sheet resistance value or an X-ray photoelectron spectroscopy (XPS).

In the present embodiment, the first temperature may be a first temperature range that is a predetermined temperature range. In the example shown in FIG. 6, the inside of the chamber is maintained at a constant temperature of, for example, 400° C. as the first temperature from the time t60 to the time t63, but in the present embodiment, the temperature in the chamber need not be constant. In the present embodiment, the temperature in the chamber may change from the time t60 to the time t63, for example, within the first temperature range of 390° C. or higher and 410° C. or lower. For example, from the time t60 to the time t63, the temperature in the chamber may decrease from 400° C. to 390° C. within the first temperature range. Alternatively, from the time t60 to the time t63, for example, the temperature in the chamber may change within the first temperature range of 400° C. or higher, 490° C. or higher and 510° C. or lower, around 500° C.

In addition, in the present embodiment, the second temperature may be a second temperature range. For example, in the example shown in FIG. 6, the inside of the chamber is maintained at a constant temperature of, for example, 200° C. as the second temperature from the time t64 to the time t67, but in the present embodiment, the temperature in the chamber need not be constant. The temperature in the chamber may change from the time t64 to the time t67, for example, within the second temperature range of 190° C. or higher and 210° C. or lower.

In addition, the case where the substrate 10 on which the oxide semiconductor is formed is loaded into the chamber (S402) and the temperature in the chamber is set to the first temperature (S404) is described as an example with reference to FIG. 4 in the manufacturing method of a semiconductor device according to the present embodiment, but the present disclosure is not limited thereto. As described above with reference to FIG. 6, the substrate 10 may be loaded into the chamber after the temperature in the chamber is set to the first temperature (or a temperature in the first temperature range).

In the present embodiment, while the oxidizing gas is supplied into the chamber, for example, from the time t62 to the time t65 in FIG. 6, or at a part of the period from the time t62 to the time t65, the pressure in the chamber may be, for example, 100 Torr or more. That is, at this time, the pressure in the chamber may be 13332 Pa or more. For example, at this time, the pressure in the chamber may be 760 Torr or more (101325 Pa or higher). The pressure from the time t62 to the time t65 or at a part of the period from the time t62 to the time t65 may be substantially the same as the pressure from the time t60 to the time t61 or from the time t66 to the time t67 when the N₂ gas is supplied. When the oxidizing gas is supplied, the oxygen amount contained in the oxide semiconductor 70 can be increased by making the pressure relatively high.

In addition, in the present embodiment, the first temperature may be 300° C. or higher. By setting the first temperature to 300° C. or higher, such as 400° C., oxygen can be more effectively supplied to the oxide semiconductor 70.

In addition, the first temperature may be 600° C. or lower. When it is desired to inhibit crystallization of the oxide semiconductor and the oxide semiconductor has an amorphous structure, it is preferable that the first temperature is 600° C. or lower.

In the present embodiment, the difference between the temperature (first temperature) in the chamber at the time t62 and the temperature in the chamber at the time t64 may be 100° C. or higher. For example, the first temperature may be adjusted to be 400° C. or higher and the second temperature may be adjusted to be 200° C. or lower. In addition, in the present embodiment, the second temperature may be 250° C. or lower.

In the present embodiment, as the oxidizing gas supplied into the chamber, at least one of oxygen (O₂), ozone (O₃), water vapor (H₂O), nitric oxide (NO), and dinitrogen monoxide (N₂O) may be used.

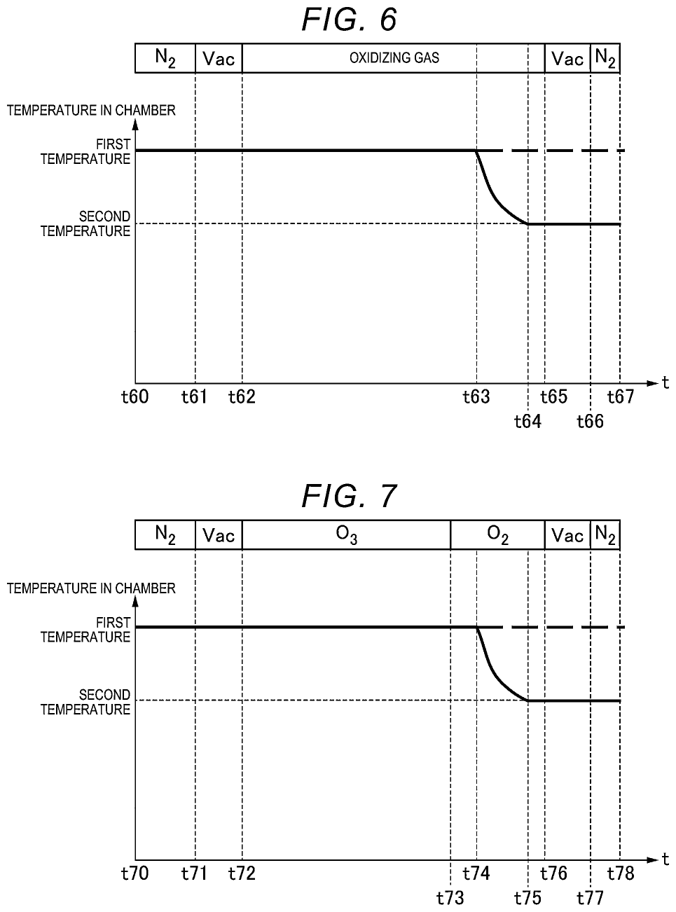

In addition, in the present embodiment, the type of the oxidizing gas supplied to the chamber may be switched from a first oxidizing gas to a second oxidizing gas in the middle. For example, the supply of the first oxidizing gas may be stopped and the second oxidizing gas may be supplied before lowering of the temperature in the processing furnace 210 (chamber) from the first temperature is started. FIG. 7 shows a time change of the temperature in the chamber and the supplied gas at this time.

As shown in FIG. 7, the ozone gas may be supplied from the time t72 to the time t73, and the oxygen gas having a smaller oxidizing power than that of the ozone gas may be supplied from the time t73 to the time t76. By switching from the ozone gas to the oxygen gas, the unloading of the substrate 10 can be performed more safely. In addition, the vacuum drawing from the time t76 to the time t77 can be omitted.

The supply of the oxygen gas is started at the time t73, and the temperature lowering in the chamber (temperature lowering from the first temperature) is started at the time t74. The temperature in the chamber reaches the second temperature at the time t75, and the supply of the oxygen gas is stopped at the time t76. That is, the vacuum drawing in the chamber is started at the time t76.

As shown in FIG. 7, the processing from the time t70 to the time t72 may be the same as the processing from the time t60 to the time t62 described with reference to FIG. 6. That is, at the time t70, the substrate 10 is loaded into the chamber with the temperature in the chamber set to, for example, 400° C., and the nitrogen gas is supplied into the chamber when the substrate is loaded. From the time t71, the nitrogen gas in the chamber is removed by using the vacuum pump 280, and the inside of the chamber is made a vacuum. In addition, at the time t72, an oxidizing gas such as an ozone gas is supplied into the chamber.

By supplying a sufficient amount of oxygen to the oxide semiconductor 70 in the period in which the temperature in the chamber is the first temperature, the second oxidizing gas having a small oxidizing power can be used in the period in which the temperature is lower than the first temperature. It is not preferable to use a gas other than the oxidizing gas instead of the second oxidizing gas. This is because the oxygen desorption from the oxide semiconductor is likely to occur by using a gas other than the oxidizing gas.

At this time, the oxidizing power of the first oxidizing gas may be equal to or larger than the oxidizing power of the second oxidizing gas. As the second oxidizing gas, a gas containing oxygen (O₂), or oxygen (O₂) and nitrogen (N₂) may be used. In the present embodiment, the oxidizing power of the first oxidizing gas and/or the second oxidizing gas means the ability to oxidize other substances (in the present embodiment, the oxide semiconductor 70 of the substrate 10). The relationship between the strength of the oxidizing power is shown, for example, by the thickness of the oxide film when the film to be oxidized is oxidized at the same temperature and the same pressure. When the same target object is oxidized for a predetermined time under the same condition (that is, the same temperature and the same pressure), when the thickness of the oxide film formed on the target object by the first oxidizing gas is larger than the thickness of the oxide film formed on the target object by the second oxidizing gas, it can be said that the oxidizing power of the first oxidizing gas is larger than the oxidizing power of the second oxidizing gas.

In the present embodiment, the first oxidizing gas and the second oxidizing gas may be different oxidizing gases. For example, an ozone gas may be used as the first oxidizing gas, and an oxygen gas may be used as the second oxidizing gas. Alternatively, the first oxidizing gas and the second oxidizing gas may be the same oxidizing gas. For example, both the first oxidizing gas and the second oxidizing gas may be an oxygen gas. At this time, the oxidizing power of the first oxidizing gas and the oxidizing power of the second oxidizing gas are the same. In addition, the same oxidizing gas such as an oxygen gas can be continuously supplied to the chamber without switching the oxidizing gas supplied to the chamber.

According to the study by the present disclosers and the like, when the oxygen gas is used as both the first oxidizing gas and the second oxidizing gas, and when the process according to the present embodiment (process described above with reference to FIG. 6 and the like) is performed under the same conditions except that the ozone gas is used as the first oxidizing gas and the oxygen gas is used as the second oxidizing gas, the oxygen content in the oxide semiconductor 70 can be increased when the ozone gas is used as the first oxidizing gas and the oxygen gas is used as the second oxidizing gas. This is because it is considered that the amount of oxygen supplied by the first oxidizing gas can be increased by using an oxidizing gas having a larger oxidizing power as the first oxidizing gas.

In addition, in the present embodiment, as described above with reference to FIG. 6, when the substrate 10 is loaded into the chamber, a nitrogen gas (N₂) may be supplied into the chamber. When the substrate 10 is loaded into the chamber containing the oxidizing gas, the components and the like near the chamber may be oxidized. The nitrogen gas may be supplied into the chamber before the substrate is loaded. In particular, when an oxidizing gas having a relatively large oxidizing power is used, it is considered that oxidation of components and the like near the chamber is likely to proceed. When the substrate 10 is loaded into the chamber, the oxidation of the components and the like near the chamber can be prevented by supplying the nitrogen gas.

In addition, after the substrate is loaded into the chamber, the nitrogen gas may be removed from the chamber. Thereafter, the inside of the chamber may be made a vacuum in a state where the nitrogen gas is removed from the chamber. At this time, the pressure in the chamber may be, for example, 1 Torr or less (133 Pa or less). That is, in the present embodiment, the inside of the chamber may be in a vacuum state by setting, for example, the pressure inside the chamber to 1 Torr or less (133 Pa or less). By making the inside of the chamber a vacuum, for example, the nitrogen gas supplied into the chamber can be more reliably removed.

Thereafter, the pressure in the chamber may be increased to, for example, 100 Torr or more (13332 Pa or more) as described above. When the first oxidizing gas is supplied into the chamber, the pressure in the chamber may be 100 Torr or more. Thereafter, after the temperature in the chamber is lowered to the second temperature, the inside of the chamber may be made a vacuum, for example, the pressure in the chamber may be 133 Pa or less. By making the inside of the chamber a vacuum after the first oxidizing gas is removed in the same manner as when the inside of the chamber is made a vacuum after the nitrogen gas is supplied, the first oxidizing gas can be more reliably removed.

Thereafter, a nitrogen gas may be supplied into the chamber when the substrate 10 is unloaded from the chamber at time t78. Thereafter, the substrate 10 may be unloaded from the chamber in a state where the nitrogen gas is supplied into the chamber (for example, in a state where the inside of the chamber is in the nitrogen gas atmosphere). By supplying the nitrogen gas into the chamber when the substrate 10 is unloaded in the same manner as when the nitrogen gas is supplied into the chamber when the substrate 10 is loaded, oxidation of the components and the like around the chamber can be prevented.

In the example shown in FIG. 7 as well, as in the example shown in FIG. 6 described above, the first temperature may be the first temperature range, and the second temperature may be the second temperature range. Therefore, the temperature in the chamber need not be constant from the time t70 to the time t74, and the temperature in the chamber also need not be constant from the time t75 to the time t78. For example, from the time t70 to the time t74, the temperature in the chamber may change within the first temperature range around 400° C., which is a range of 390° C. or higher and 410° C. or lower. In addition, the temperature in the chamber may also change from the time t75 to the time t78, for example, within the second temperature range of 190° C. or higher and 210° C. or lower.

### Second Embodiment

Although the case where the temperature in the chamber is raised to the first temperature after the substrate 10 is loaded and before the oxidizing gas is supplied is described as an example in the first embodiment, the present disclosure is not limited thereto. In the present embodiment, for example, after the substrate 10 is loaded, the nitrogen gas may be removed from the chamber, the inside of the chamber may be made in a vacuum state, and then the temperature raising to the first temperature may not be started until the supply of the oxidizing gas is started. That is, the temperature raising to the first temperature may be started after the oxidizing gas is supplied into the chamber.

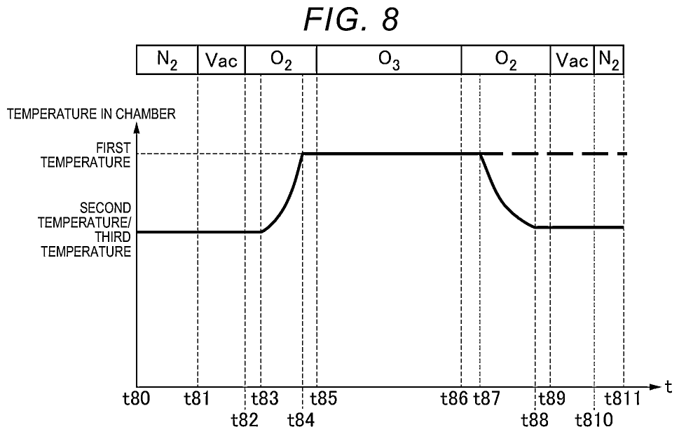

A manufacturing method of a semiconductor device in this case will be described with reference to FIG. 8. FIG. 8 shows a time change of the temperature in the chamber similar to that in FIG. 6. As in FIG. 6, FIG. 8 also shows the gas supplied to the chamber.

As shown in FIG. 8, in the manufacturing method of a semiconductor device of the present embodiment, the substrate 10 is loaded into the chamber at the time t80. When the substrate 10 is loaded, a nitrogen gas may be supplied into the chamber. In addition, the temperature in the chamber at this time is, for example, a temperature lower than the first temperature (third temperature in the present embodiment). The third temperature in the present embodiment may be substantially the same as the above-described second temperature, which is the temperature after the temperature lowering from the first temperature, which is the temperature in the chamber when the first oxidizing gas is supplied, and is, for example, 200° C. The temperature in the chamber may be set to the third temperature after the supply of the nitrogen gas into the chamber is started, or the supply of the nitrogen gas into the chamber may be started after the temperature in the chamber is set to the third temperature. In addition, the nitrogen gas may be supplied into the chamber while adjusting the temperature in the chamber to the third temperature.

Next, from the time t81, the nitrogen gas in the chamber is removed by using the vacuum pump 280, and the inside of the chamber is made a vacuum. At this time, for example, the pressure in the chamber may be 133 Pa or less.

Subsequently, at the time t82, a third oxidizing gas such as an oxygen gas is supplied into the chamber.

In a state where the third oxidizing gas is supplied into the chamber, that is, in a state where the inside of the chamber is in a third oxidizing gas atmosphere, the temperature raising inside the chamber is started at the time t83. At the time t84, the temperature in the chamber is, for example, 400° C. (first temperature in the present embodiment) in a state where the third oxidizing gas is supplied into the chamber.

Thereafter, at the time t85, the supply of the first oxidizing gas such as an ozone gas is started. In this manner, the inside of the chamber is in a first oxidizing gas atmosphere in a state where the temperature in the chamber is the first temperature.

Next, at the time t86, the supply of the first oxidizing gas into the chamber is stopped, and for example, the supply of the second oxidizing gas such as an oxygen gas is started. The temperature in the chamber is lowered from the time t87 in a state where the second oxidizing gas is supplied into the chamber. The temperature in the chamber is, for example, 200° C. (second temperature in the present embodiment) at the time t88.

Thereafter, from the time t89 to the time t810, the second oxidizing gas is removed by using the vacuum pump 280, and the inside of the chamber is made a vacuum. At this time, for example, the pressure in the chamber is set to 133 Pa or less. By making the inside of the chamber a vacuum after the second oxidizing gas is removed in the same manner as the above-described embodiment, the second oxidizing gas can be more reliably removed.

Thereafter, in the same manner as the process described with reference to FIG. 6, the supply of the nitrogen gas into the chamber is started at the time t810. Subsequently, at the time t811, the nitrogen gas is supplied into the chamber, and the substrate 10 is unloaded.

In the process described with reference to FIG. 8, the temperature in the chamber is maintained at a relatively low third temperature while the nitrogen gas is supplied into the chamber and while the inside of the chamber is in a vacuum. Further, when the third oxidizing gas is supplied into the chamber, the temperature in the chamber is lower than the first temperature. The temperature in the chamber is raised from the third temperature to the first temperature while the third oxidizing gas is supplied. Further, when the second oxidizing gas is supplied into the chamber, the temperature in the chamber is lower than the first temperature. The temperature in the chamber is lowered from the first temperature to the second temperature while the second oxidizing gas is supplied. In this way, by providing a time for maintaining the temperature in the chamber at the first temperature or lower, the desorption of oxygen from the oxide semiconductor can be reduced.

As shown in FIG. 8, the inside of the chamber can be made in a second oxidizing gas atmosphere such as an oxygen gas when the temperature is lowered from the first temperature to the second temperature after the supply of the first oxidizing gas (time t87 to time t88) by making the inside of the chamber in the second oxidizing gas atmosphere such as an oxygen gas during the time when the temperature is raised from the third temperature to the first temperature (time t83 to time t84).

As described above, the third temperature may be, for example, the same as or substantially the same as the second temperature, for example, a difference between the first temperature and the third temperature may be 100° C. or higher, and the third temperature may be 250° C. or lower.

In addition, in the example shown in FIG. 8 as well, as in the example shown in FIGS. 6 and 7 described above, the first temperature may be the first temperature range, the second temperature may be the second temperature range, and the third temperature may be a third temperature range. Therefore, the temperature in the chamber need not be constant from the time t84 to the time t87, the temperature in the chamber also need not be constant from the time t80 to the time t83, and the temperature in the chamber also need not be constant from the time t88 to the time t811. For example, from the time t84 to the time t87, the temperature in the chamber may change within the first temperature range around 400° C., which is a range of 390° C. or higher and 410° C. or lower. In addition, from the time t80 to the time t83, for example, the temperature in the chamber may change within the third temperature range of 190° C. or higher and 210° C. or lower, and from the time t88 to the time t811, for example, the temperature in the chamber may also change within the second temperature range of 190° C. or higher and 210° C. or lower.

In the above-described embodiment, the process of supplying the above-described oxidizing gas may be performed on the substrate 10 on which the insulating layer 63 is provided above the oxide semiconductor 70. At this time, for example, oxygen that permeates the insulating layer 63 is supplied to the oxide semiconductor 70. That is, at this time, the insulating layer 63 is an oxygen permeable layer with respect to the oxide semiconductor 70. At this time, when the thickness of the insulating layer 63 serving as the oxygen permeable layer is 5 nm or more, the pressure and the temperature in the chamber may be set to a high pressure and/or a high temperature depending on the film thickness.

In the above-described embodiment, the insulating layer 63 is provided above the oxide semiconductor 70, and the oxidizing gas is supplied into the chamber, so that the oxygen may be supplied to the oxide semiconductor by permeating the insulating layer 63 of the substrate 10, and the pressure in the chamber when the first oxidizing gas is supplied may be 200 Torr or more (26664 Pa or more) when the thickness of the insulating layer 63 is 5 nm or more. For example, when the thickness of the insulating layer 63 is 200 nm or more, the pressure in the chamber during the supply of the first oxidizing gas may be 600 Torr or more (79993 Pa or more). According to the study by the present disclosers and the like, for example, when the thickness of the insulating layer 63 is set to 300 nm, it was found that the semiconductor device manufactured with the pressure in the chamber during the supply of the first oxidizing gas set to approximately 700 Torr (approximately 93326 Pa) shows the desired current-voltage characteristics.

In the above-described embodiment, the insulating layer 63 may have a lower density than that of the other layers (for example, the layers other than the insulating layer 63 provided in the semiconductor device 101 described with reference to FIG. 2). In addition, the insulating layer 63 may be formed of at least one of silicon dioxide (SiO₂) and aluminum oxide (Al₂O₃). Further, the insulating layer 63 may contain nitrogen, and the degree of freedom in diffusion of oxygen in the insulating layer 63 can be adjusted by adjusting the nitrogen contained in the insulating layer 63.

In the above-described embodiment, the first temperature may be 300° C. or higher and 600° C. or lower. According to the study by the present disclosers and the like, for example, the first temperature is preferably higher in a range of 300° C. or higher and 600° C. or lower, so that the oxygen supply amount via the first oxidizing gas can be further increased. For example, when the process according to the present embodiment is performed under the same conditions except that the first temperature is set to 400° C. or 420° C., when the first temperature is set to 420° C., the contained oxygen amount can be increased as compared to when the first temperature is set to 400° C.

Similarly, by increasing the pressure in the chamber while the first oxidizing gas is supplied, the oxygen supply amount can be increased, which is preferable. For example, when the process according to the present embodiment is performed under the same conditions except that the pressure in the chamber when the first oxidizing gas is supplied is set to 9 Torr (approximately 1200 Pa) and 760 Torr (approximately 101325 Pa), when the pressure in the chamber is set to approximately 101325 Pa, the contained oxygen amount can be increased as compared with when the pressure in the chamber is set to approximately 1200 Pa.

In the above-described embodiment, a case where the inside of the chamber is made a vacuum after the oxidizing gas (first oxidizing gas or second oxidizing gas) is removed from the chamber is described as an example, but for example, when the oxidizing power of the oxidizing gas to be used is relatively small, without making the inside of the chamber a vacuum, the next process (for example, supply of nitrogen gas) may be started.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A manufacturing method, comprising:
loading a substrate into a chamber, the substrate including oxide semiconductor;
configuring a temperature in the chamber to a first temperature;
supplying an oxidizing gas into the chamber;
lowering the temperature in the chamber from the first temperature;
stopping supplying the oxidizing gas into the chamber after lowering the temperature; and
unloading the substrate from the chamber after the temperature in the chamber reaches a second temperature lower than the first temperature.

2. The manufacturing method according to claim 1, further comprising:
stopping supplying the oxidizing gas after the temperature in the chamber reaches the second temperature.

3. The manufacturing method according to claim 1, further comprising:
configuring a pressure in the chamber to be equal to or higher than 13332 Pa, while supplying the oxidizing gas,
wherein the first temperature is equal to or higher than 300° C.

4. The manufacturing method according to claim 1,
wherein a difference between the first temperature and the second temperature is equal to or higher than 100° C.

5. The manufacturing method according to claim 1,
wherein the oxidizing gas includes at least one of oxygen (O₂), ozone (O₃), water vapor (H₂O), nitric oxide (NO), or dinitrogen monoxide (N₂O).

6. The manufacturing method according to claim 1,
wherein the oxidizing gas includes a first oxidizing gas and a second oxidizing gas, and
an oxidizing power of the first oxidizing gas is equal to or higher than an oxidizing power of the second oxidizing gas.

7. The manufacturing method according to claim 6, further comprising:
supplying the second oxidizing gas into the chamber after stopping supplying the first oxidizing gas into the chamber;
lowering the temperature in the chamber from the first temperature after supplying the second oxidizing gas into the chamber; and
stopping supplying the second oxidizing gas into the chamber after starting the temperature lowering.

8. The manufacturing method according to claim 7, further comprising:
stopping supplying the second oxidizing gas after the temperature in the chamber reaches the second temperature.

9. The manufacturing method according to claim 6,
wherein the second oxidizing gas contains oxygen (O₂), or oxygen (O₂) and nitrogen (N₂).

10. The manufacturing method according to claim 1, further comprising:
supplying a nitrogen gas into the chamber when loading the substrate into the chamber;
stopping supplying the nitrogen gas into the chamber after loading the substrate into the chamber;
supplying the oxidizing gas into the chamber after stopping supplying the nitrogen gas into the chamber; and
supplying the nitrogen gas into the chamber after stopping supplying the oxidizing gas into the chamber and when unloading the substrate from the chamber.

11. The manufacturing method according to claim 1,
wherein supplying the oxidizing gas into the chamber includes supplying a first oxidizing gas, supplying a second oxidizing gas, and supplying a third oxidizing gas, and
the manufacturing method further comprises:
setting the temperature in the chamber to a third temperature lower than the first temperature,
raising the temperature in the chamber from the third temperature after starting supplying the third oxidizing gas into the chamber at the third temperature,
stopping supplying the third oxidizing gas into the chamber after the temperature in the chamber reaches the first temperature,
supplying the first oxidizing gas into the chamber after stopping supplying the third oxidizing gas into the chamber,
supplying the second oxidizing gas into the chamber after stopping supplying the first oxidizing gas into the chamber,
lowering the temperature in the chamber from the first temperature after supplying the second oxidizing gas into the chamber, and
stopping supplying the second oxidizing gas into the chamber after lowering the temperature.

12. The manufacturing method of a semiconductor device according to claim 1,
wherein an insulating layer is provided above the oxide semiconductor.
